(19) United States
(12) Patent Application Publication
(10) Pub. No.: US 2004/0189424 A1
(43) Pub. Date: Sep. 30, 2004

(54) FBAR mass loading process using selective dry etching

(76) Inventors: David W. Hula, Fort Collins, CO (US); Carrie A. Guthrie, Fort Collins, CO (US); Ronnie P. Varghese, Fort Collins, CO (US); Stephen L. Miller, Fort Collins, CO (US); Jennifer R. Bradford, Corvallis, OR (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/403,368

(22) Filed: Mar. 31, 2003

(51) Int. Cl. H03H 9/54

(52) U.S. Cl. 333/188; 333/189; 310/312

(57) ABSTRACT

A method and apparatus is presented. The method produces a Film Bulk Acoustic Resonator (FBAR) structure. A piezoelectric layer is provided and a series of manufacturing steps are performed to deposit a thin mass-load layer above the piezoelectric layer. Further, an electrode material is deposited on the thin mass-load layer after portions of the thin mass-load layer have been removed. The electrode material includes a non-mass-loaded region positioned above the piezoelectric layer and a mass-loaded region positioned above the mass-load layer.

### BACKGROUND OF THE INVENTION

1. Description of the Related Art

A piezoelectric thin film can be used to convert electrical energy into mechanical energy and mechanical energy into electrical energy. Film Bulk Acoustic Resonators (FBAR) consists of a piezoelectric thin film positioned between two metal layers (i.e., metal electrodes). Conventional FBAR resonators are created using a thin film semiconductor process to build a metal-aluminum nitride metal sandwich.

When an alternating electrical potential is applied across the metal-aluminum nitride metal sandwich, the entire aluminum nitride (AIN) layer expands and contracts creating a vibration or resonance. The resonance occurs within the body of the material and is often referred to as a bulk resonance. The electric field causes the bulk or AIN to expand and contract.

The expanding and contracting AIN layer creates a high mechanical (i.e., acoustic) resonance. Using the relationship of frequency times wavelength equals speed, for a given frequency of resonance, sound waves traveling at several hundred meters per second will have much shorter wavelengths than electrical signals moving at the speed of light. Consequently, the dimensions of an acoustic resonator at a given frequency are several orders of magnitude smaller than a coaxial-based resonator at a similar frequency. As a result, acoustic devices may be implemented in a semiconductor device.

As an alternating voltage is applied across the AIN, a polarization vector (P) will change in phase based on the alternating voltage. During operation, at one voltage, (P) will be in phase with a vector (E) created by the applied potential creating a series resonance. At another voltage, (P) will be 180 degrees out of phase with (E) creating parallel resonance. A piezoelectric coupling is used to access the acoustic resonance (i.e., parallel resonance) and to create an electric resonator.

A variety of procedures have been developed for manufacturing FBAR devices. FIG. 1 displays a flow diagram depicting the steps associated with an FBAR manufacturing process. In the first step of the process, an exposed piezoelectric layer is provided as stated at 100. A top electrode material, such as molybdenum (Mo), is deposited as stated at 102. The top electrode material is then patterned with a negative photo resist as stated at 104. A thin mass-loading material, such as molybdenum (Mo), is then deposited as stated at 106. The mass-loading material is then removed (i.e., liftoff process) from undesirable areas of the device as stated at 108. Lastly, subsequent device processing is performed to complete the manufacturing of the FBAR device as stated at 110.

The foregoing method requires a low-power Mo deposition technique so that the photo resist is not damaged and the sidewall of the photo resist is not coated during the mass-load Mo deposition. Damaging the photo resist or the sidewall coating of the photo resist results in residual material being left behind on the surface after a liftoff process. In addition, residual material produces discharge paths that lower the electrostatic discharge (ESD) resilience of the FBAR device.

Thus, there is a need for a method of manufacturing an FBAR device, which tightly controls the photo resist sidewall profile. There is a need for a method of manufacturing FBAR devices, which allows a manufacturer to use positive photo resist which are more readily available. There is a need for a method of manufacturing FBAR devices that eliminates residual material on the surface of the device. There is a need for a method of manufacturing FBAR devices that allows a designer to use a higher power mass-load Mo deposition process, if desired. Lastly, there is a need for a method of manufacturing FBAR devices, which allows the designer to increase the thickness of the mass-load layer, if desired.

### SUMMARY OF THE INVENTION

A method of manufacturing an FBAR structure (i.e., device) is presented. In one embodiment of the present invention, a thin mass-load layer is deposited on a piezoelectric layer. The thin mass-load layer is patterned with a photo resist and then removed from areas where a high resonance is desired. The method of manufacturing may be performed recursively and, as such, any number of thin mass-load layers may be implemented to construct the FBAR structure.

Using the foregoing method of manufacturing an FBAR structure is produced. In one embodiment of the present invention, the FBAR structure includes a thin mass-load layer positioned between a piezoelectric material and an electrode. The electrode material includes a non-mass-loaded region positioned above the piezoelectric region and a mass-loaded region positioned above the mass-load layer.

In another embodiment of the present invention, an FBAR structure includes a first thin mass-load layer and a second thin mass-load layer positioned between a piezoelectric material and an electrode. The electrode material includes a non-mass-loaded region positioned above the piezoelectric region and a mass-loaded region positioned above the first thin mass-load layer and positioned above the second thin mass-load layer.

The method of manufacturing implemented in accordance with the teachings of the present invention (1) tightly controls the photo resist sidewall profile in an FBAR structure; (2) enables the use of positive photo resist which are more readily available; (3) eliminates residual material on the surface of an FBAR structure; (4) enables the use of higher power Mo deposition process, if desired; (5) increases the thickness of the mass-load layer, if desired; (6) enables profile control of the mass-load material sidewall, if desired; and (7) enables improved mass-load material line width control.

A method of manufacturing comprises the steps of depositing a mass-load layer on a piezoelectric layer; patterning the mass-load layer with a photo resist; removing a portion of the mass-load layer leaving a remainder of the mass-load layer; and removing the photo resist from the remainder of the mass-load layer.

A structure comprises a piezoelectric layer; a mass-load layer positioned above the piezoelectric layer; and an electrode material comprising a non-mass-loaded region positioned above the piezoelectric layer and a mass-loaded region positioned above the piezoelectric layer.

A structure comprises a piezoelectric layer; an electrode material; and a mass-load layer positioned between the piezoelectric layer and the electrode material.

A structure comprises a first mass-load region positioned above a piezoelectric layer; a second mass-loaded region positioned above the piezoelectric layer; and an electrode material positioned above the first mass-load region and positioned above the second mass-load region.

### BRIEF DESCRIPTION OF THE DRAWINGS

FIG. 1 displays a flow diagram of a prior art method of manufacturing an FBAR structure.

FIG. 2 displays a flow diagram of a method of manufacturing an FBAR structure in accordance with the teachings of the present invention.

FIGS. 3A-3F display a cross-sectional diagram of an embodiment of an FBAR structure manufactured in accordance with the teachings of the present invention.

FIGS. 4A-4J display a cross-sectional diagram of an alternate embodiment of an FBAR structure manufactured in accordance with the teachings of the present invention.

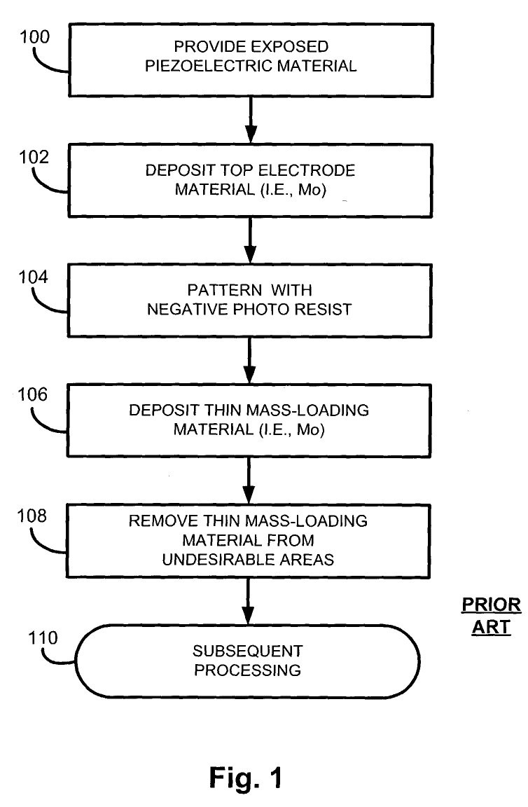

### DETAILED DESCRIPTION

While the present invention is described herein with reference to illustrative embodiments for particular applications, it should be understood that the invention is not limited thereto. Those having ordinary skill in the art and access to the teachings provided herein will recognize additional modifications, applications, and embodiments within the scope thereof and additional fields in which the present invention would be of significant utility.

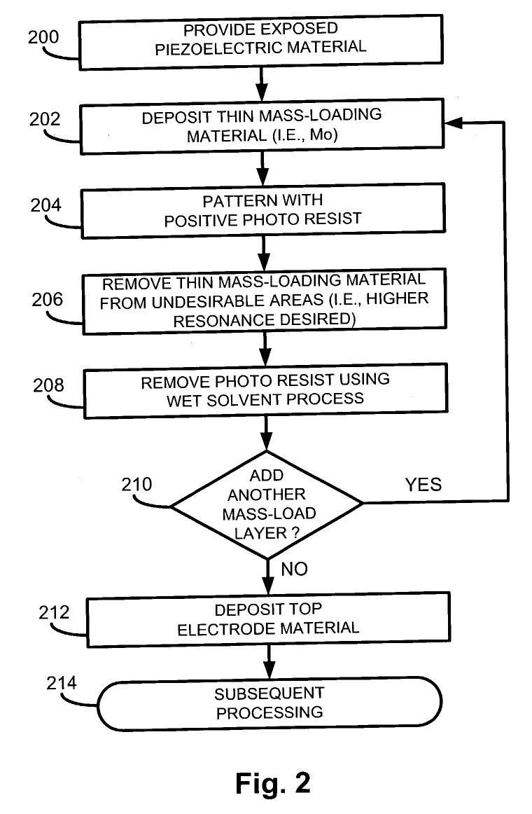

FIG. 2 displays a flow diagram of a method of manufacturing an FBAR structure. In one embodiment, a piezoelectric material is provided as stated at 200. The piezoelectric material may include aluminum nitride, zinc oxide, etc. At step 202, a thin mass-loading material is deposited using a chemical vapor deposition technique, a sputtering technique, etc. The thin mass-loading material may include Mo, aluminum, tungsten, etc. The thin mass-loading material may measure 20 angstroms to 2000 angstroms. However, it should be appreciated that the thin mass-loading material may measure less than 20 angstroms and more than 2000 angstroms and still remain within the scope of the present invention.

The thin mass-loading material is patterned with a positive photo resist as stated at step 204. The positive photo resist is thick enough to withstand an etching process. At step 206, the thin mass-loading material is removed from areas in which a higher resonance is desired. Removing the thin mass-loading material from areas in which a higher resonance is desired leaves a portion (i.e., remainder) of the thin mass-loading material. The thin mass-loading material may be removed with techniques, such as a dry-selective etching process, a wet-selective etching process, etc.

At step 208, the positive photo resist is removed. In one embodiment of the present invention, a wet-solvent process is used to remove the positive photo resist. For example, strip chemistries, such as acetone, may be used to remove the positive photo resist. Using the wet-solvent process avoids the oxidation of the thin layer of Mo (i.e., thin mass-loading material). The wet solvent may be applied with a spray-processing tool, in a bench setup, in a tank setup, etc.

At step 210, a determination is made with respect to depositing another thin mass-load layer. If another this mass-load layer will be deposited, the method depicted in FIG. 2 loops back to step 202 and a second thin mass-loading material is applied. If another mass-loading layer is not desired, then the method proceeds to step 212.

At step 212, a top electrode material is deposited on the remainder of the thin mass-loading material and the piezoelectric material that is not covered by the remainder of the thin mass-loading material. In one embodiment, the top electrode material may be about 1000 angstroms or more in thickness. The top electrode material is deposited using Chemical Vapor Deposition (CVD), sputtering techniques, etc. At 214, subsequent processing is performed. Subsequent processing may include but is not limited to patterning and etching the top electrode material, depositing and patterning other materials to make other electrical connections, or adding other protective layers on the structure.

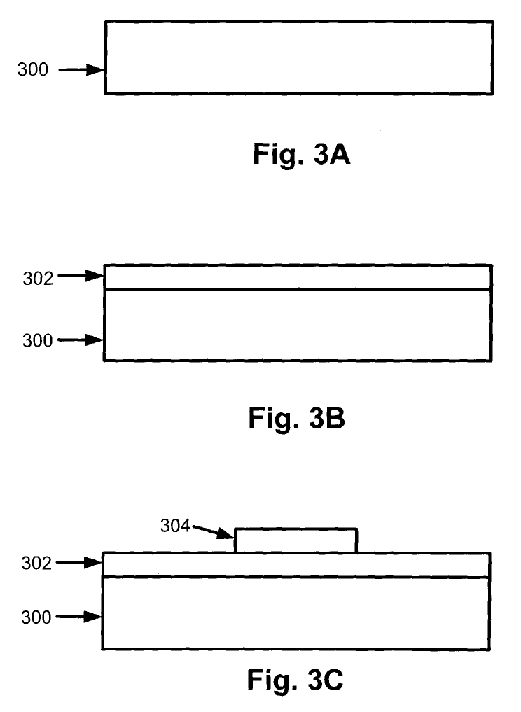

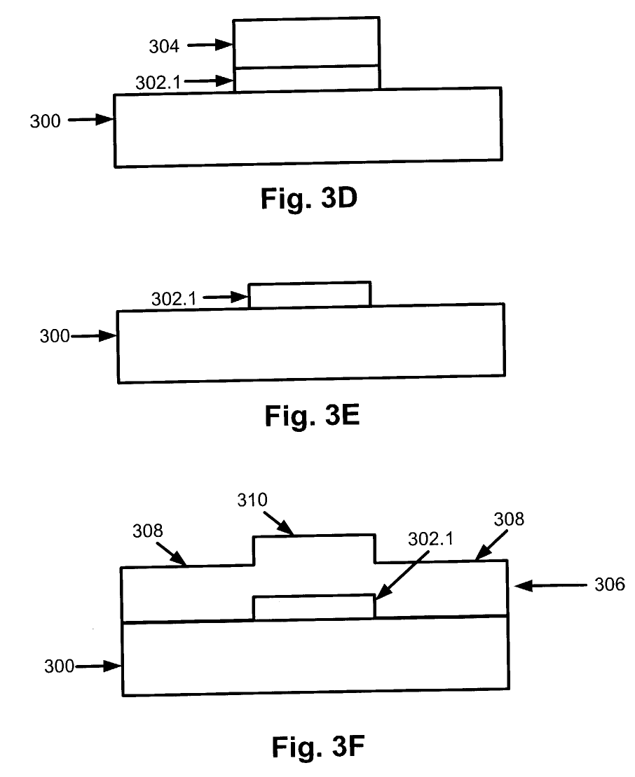

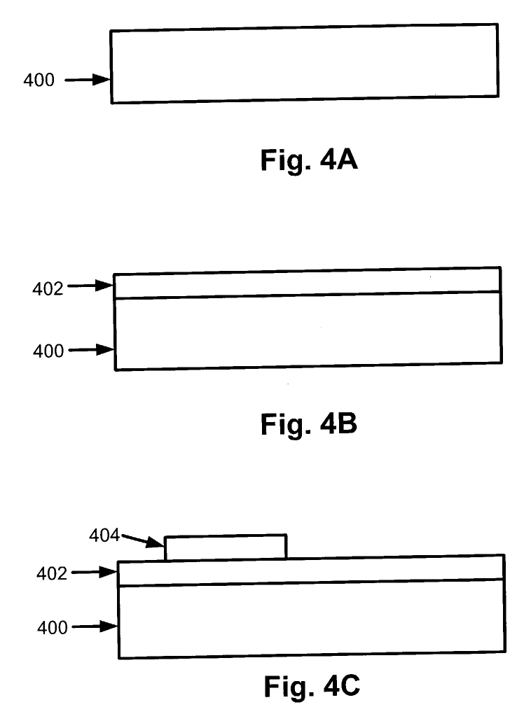

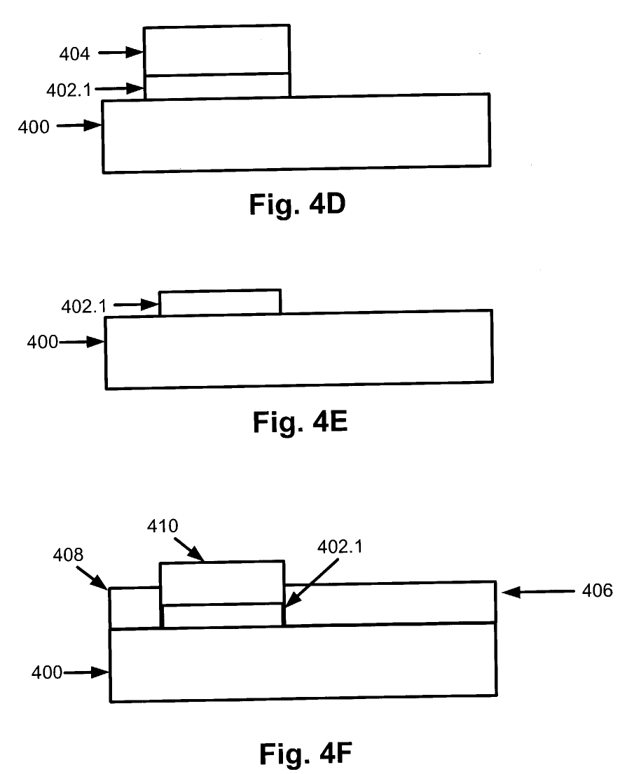

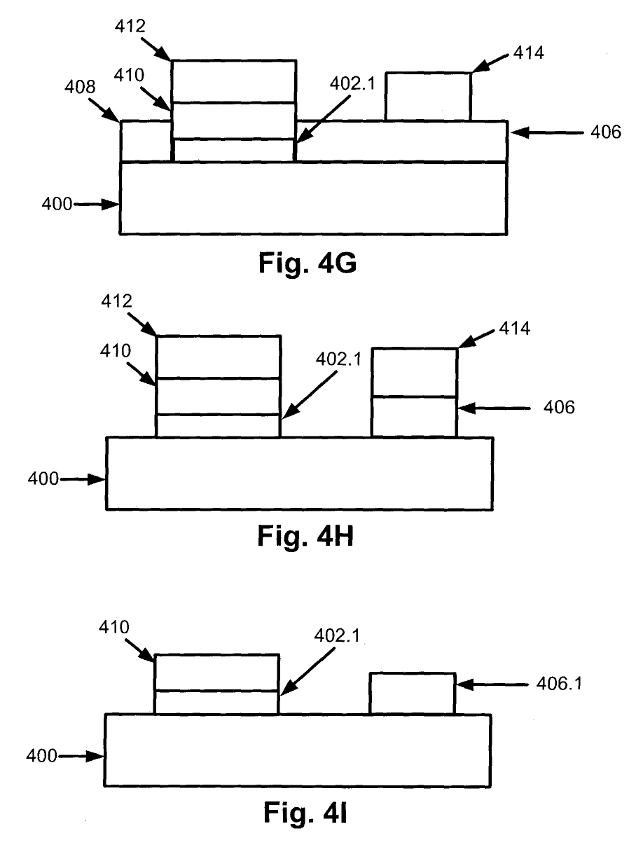

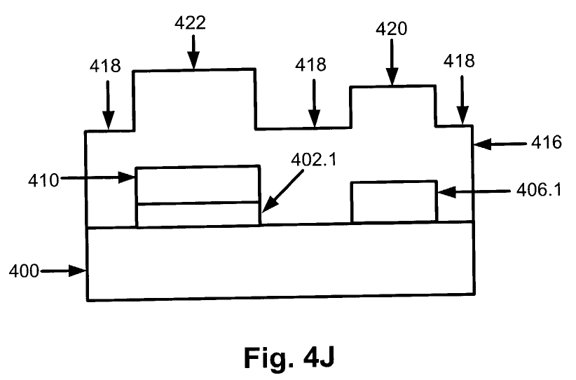

FIGS. 3A-3F display a cross-sectional diagram of an embodiment of an FBAR structure manufactured in accordance with the teachings of the present invention. In FIG. 3A, a piezoelectric layer is shown as 300. In one embodiment, the piezoelectric layer is deposited on a bottom electrode material (not shown in FIG. 4A). In FIG. 3B, a thin mass-load layer 302 is applied to the piezoelectric layer 300. In FIG. 3C, a positive photo resist layer 304 is positioned above the thin mass-load layer 302, which is positioned above the piezoelectric layer 300. In FIG. 3D, a portion of the thin mass-load layer is etched away leaving the remainder of the thin mass-load layer 302.1 deposited between the piezoelectric layer 300 and the positive photo resist layer 304. In FIG. 3E, a photo resist layer (not shown in FIG. 3E) is removed leaving the remainder of the thin mass-load layer 302.1 and the piezoelectric layer 300.

In FIG. 3F, a thick top electrode material 306 is deposited above the piezoelectric layer 300 and the remainder of the thin mass-load layer 302.1. The thick top electrode material 306 includes a thick electrode material positioned above the non-mass-load region 308 and a thick electrode material positioned above a mass-loaded region 310. FIG. 3F details an embodiment of a structure implemented in accordance with the teachings of the present invention. It should be appreciated that subsequent processing may be performed on the structure depicted in FIG. 3F. Subsequent processing may include but is not limited to patterning and etching the top electrode material, depositing and patterning other materials to make other electrical connections, or adding other protective layers on the structure.

FIGS. 4A-4J display a cross-sectional diagram of an alternate embodiment of an FBAR structure manufactured in accordance with the teachings of the present invention. In FIG. 4A, a piezoelectric layer is shown as 400. In one embodiment, the piezoelectric layer is deposited on a bottom electrode material (not shown in FIG. 4A). In FIG. 4B, a first thin mass-load layer 402 is positioned above the piezoelectric layer 400. In FIG. 4C, a first positive photo resist layer 404 is positioned above the first thin mass-load layer 402, which is positioned above the piezoelectric layer 400. In FIG. 4D, a portion of the first thin mass-load layer 402 is etched away leaving the remainder of the first thin mass-load layer 402.1 deposited between the piezoelectric layer 400 and the first positive photo resist layer 404. In FIG. 4E, the first positive photo resist layer 404 (not shown in FIG. 4E) is removed leaving the remainder of the first thin mass-load layer 402.1 and the piezoelectric layer 400.

In FIG. 4F, a second thin mass-load layer (406, 408, 410) is deposited. In one embodiment of the present invention, the second thin mass-load layer (406, 408, 410) is one contiguous layer; however, regions of the second thin mass-load layer are defined for the purposes of discussion. The second thin mass-load layer (406, 408, 410) includes a first region of the second thin mass-load layer 406, a second region of the second thin mass-load layer 408, and a third region of the second thin mass-load layer 410. The first region of the second thin mass-load layer 406 is deposited on the piezoelectric layer 400 and is positioned relative to the remainder of the first thin mass-load layer 402.1. The second region of the second thin mass-load layer 408 is deposited on the piezoelectric layer 400 and is positioned relative to the remainder of the first thin mass-load layer 402.1 on an opposite-disposed side from the first region of the second thin mass-load layer 406. The third region of the second thin mass-load layer 410 is deposited on the remainder of the first thin mass-load layer 402.1 and is contiguous with both the first region of the second thin mass-load layer 406 and the second region of the second thin mass-load layer 408.

In FIG. 4G, a second positive photo resist layer 412 is deposited above the third region of the second thin mass-load layer 410 and a third positive photo resist layer 414 is deposited on the first region of the second thin mass-load layer 406. It should be appreciated, in one embodiment of the present invention, the second positive photo resist layer 412 and the third positive photo resist layer 414 are the same layer; however, for the purposes of discussion they are referred to independently. In FIG. 4H, the second region of the second thin mass-load layer 408 and portions of the first region of the second thin mass-load layer 406 are etched away. In FIG. 4I, the second positive photo resist layer 412 (not shown in FIG. 4I) is removed from the third region of the second thin mass-load layer 410 and the third positive photo resist layer 414 (not shown in FIG. 4I) is removed from the first region of the second thin mass-load layer 406. As a result, in FIG. 4J, the remainder of the first thin mass-load layer 402.1 and the remainder of the first region of the second thin mass-load layer 406.1 are positioned above the piezoelectric layer 400 and the third region of the second thin mass-load layer 410 is positioned above the remainder of the first thin mass-load layer 402.1.

A thick top electrode material 416 is deposited on the piezoelectric layer 400 above the remainder of the first region of the second thin mass-load layer 406.1 and above the third region of the second thin mass-load layer 410. The thick top electrode material 416 includes a non-mass-load region 418 positioned above the piezoelectric layer 400, a mass-loaded region 420 positioned above the remainder of the first region of the second thin mass-load layer 406.1, and a mass-loaded region 422 positioned above the third region of the second thin mass-load layer 410, which is positioned above the remainder of the first thin mass-load layer 402.1.

FIG. 4J details a structure implemented in accordance with the teachings of the present invention. It should be appreciated that subsequent processing may be performed on the structure depicted in FIG. 4J. Subsequent processing may include but is not limited to patterning and etching the top electrode material, depositing and patterning other materials to make other electrical connections, or adding other protective layers on the structure.

Thus, the present invention has been described herein with reference to a particular embodiment for a particular application. Those having ordinary skill in the art and access to the present teachings will recognize additional modifications, applications, and embodiments within the scope thereof.

It is, therefore, intended by the appended claims to cover any and all such applications, modifications, and embodiments within the scope of the present invention.

What is claimed is:

1. A method of manufacturing comprising the steps of:
depositing a mass-load layer above a piezoelectric layer;
patterning the mass-load layer with a photo resist;
removing a portion of the mass-load layer leaving a remainder of the mass-load layer; and
removing the photo resist from the remainder of the mass-load layer.

2. A method of manufacturing as set forth in claim 1, further comprising the step of depositing an electrode material above the remainder of the mass-load layer and above the piezoelectric layer.

3. A method of manufacturing as set forth in claim 2, wherein the electrode material is greater than 1000 angstroms thick.

4. A method of manufacturing as set forth in claim 1, further comprising the step of depositing the piezoelectric layer on an electrode material.

5. A method of manufacturing as set forth in claim 1, further comprising the step of depositing a second mass-load layer.

6. A method of manufacturing as set forth in claim 1, wherein the mass-load layer is between 20 angstroms thick and 2000 angstroms thick.

7. A method of manufacturing as set forth in claim 1, wherein the photo resist is a positive photo resist.

8. A method of manufacturing as set forth in claim 1, wherein the piezoelectric layer includes aluminum nitride.

9. A method of manufacturing as set forth in claim 1, wherein the piezoelectric layer includes zinc oxide.

10. A method of manufacturing as set forth in claim 1, wherein the mass-load layer includes molybdenum.

11. A method of manufacturing as set forth in claim 1, wherein the mass-load layer includes tungsten.

12. A method of manufacturing as set forth in claim 1, wherein the portion of the mass-load layer is removed from areas in which a higher resonant frequency is desired.

13. A method of manufacturing as set forth in claim 1, wherein the step of removing the photo resist from the remainder of the mass-load layer is performed with a wet solvent process.

14. A structure comprising:
a piezoelectric layer;
an electrode material; and
a mass-load layer positioned between the piezoelectric layer and the electrode material.

15. A structure as set forth in claim 14, further comprising a second mass-load layer positioned between the piezoelectric layer and the electrode material.

16. A structure as set forth in claim 14, further comprising a second electrode material positioned on an oppositely disposed side of the piezoelectric layer from the electrode material.

17. A structure as set forth in claim 14, wherein the mass-load layer and a second mass-load layer are both in contact with the electrode material.

18. A structure comprising:
a first mass-load region positioned above a piezoelectric layer;
a second mass-load region positioned above the piezoelectric layer; and
an electrode material positioned above the first mass-load region and positioned above the second mass-load region.

19. A structure as set forth in claim 18, the electrode material further comprising a mass-loaded region and a non-mass-loaded region, the mass-loaded region positioned above the first mass-load region and the second mass-load region and the non-mass-loaded region positioned above the piezoelectric layer.

20. A structure as set forth in claim 18, further comprising a second electrode material positioned on an oppositely disposed side of the piezoelectric layer from the electrode material.
